(19) United States
(12) Patent Application Publication
(10) Pub. No.: US 2019/0122869 A1
(43) Pub. Date: Apr. 25, 2019

(54) SUBSTRATE TREATING APPARATUS AND COMPONENTS THEREOF

(71) Applicant: SEMES CO., LTD., Chungcheongnam-do (KR)

(72) Inventors: YU DONG HAN, Daejeon (KR); DAEHYUN YANG, Suwon-si (KR)

(21) Appl. No.: 16/162,430

(22) Filed: Oct. 17, 2018

(30) Foreign Application Priority Data
Oct. 20, 2017 (KR) 10-2017-0136463

(51) Int. Cl. H01J 37/32; H01L 21/683; H01L 21/687

(52) U.S. Cl. CPC H01J 37/32715; H01L 21/6833; H01J 2237/3321; H01J 37/32495; H01J 2237/3341; H01L 21/68721

(57) ABSTRACT

A substrate treating apparatus and a component thereof are provided. The substrate treating apparatus includes a chamber having a treatment space therein, a chamber having a treatment space therein, a supporting unit to support a substrate inside the treatment space, a gas supplying unit to supply process gas into the treatment space, and a plasma source to excite the process gas inside the treatment space. The supporting unit includes a supporting plate on which the substrate is placed, and an edge ring having a ring shape, provided around the supporting plate, and formed on an upper portion thereof with a coating layer having a silicon carbide crystal developed in preferred orientation to <111> crystal direction of a beta-silicon carbide (β-SiC) crystal.

### CROSS-REFERENCE TO RELATED APPLICATIONS

This application claims priority under 35 U.S.C. § 119 to Korean Patent Application No. 10-2017-0136463 filed on Oct. 20, 2017, in the Korean Intellectual Property Office, the disclosures of which are incorporated by reference herein in their entireties.

### BACKGROUND

Embodiments of the inventive concept described herein relate to a substrate treating apparatus and a component thereof.

In order to fabricate a semiconductor device, a desired pattern is formed on a substrate through various processes such as, photolithography, etching, ashing, ion implantation, thin film deposition, and cleaning processes. Among them, the etching process, which is to remove a selected heating region from a layer formed on a substrate, includes a wet etching process and a dry etching process.

Among then, for the dry etching, an etching device is employed using plasma. In general, an electric field is formed in an inner space of a chamber to form the plasma. The electric field excites process gas provided in the chamber to be in a plasma state.

The plasma refers to the state of gas ionized while including ions, electrons and radicals. The plasma is generated due to a significantly high temperature, a strong electric field, or radio frequency electromagnetic fields. The fabrication process of a semiconductor device includes an etching process using the plasma. The etching process is performed as ion particles, which are contained in the plasma, collide with a substrate.

### SUMMARY

An embodiment of the inventive concept provides a component having a long lifespan and a substrate treating apparatus including the same.

According to an exemplary embodiment, a substrate treating apparatus may include a chamber having a treatment space therein, a supporting unit to support a substrate inside the treatment space, a gas supplying unit to supply process gas into the treatment space, and a plasma source to excite the process gas inside the treatment space. The supporting unit may include a supporting plate on which the substrate is placed, and an edge ring having a ring shape, provided around the supporting plate, and formed on an upper portion thereof with a coating layer having a silicon carbide crystal developed in preferred orientation to <111> crystal direction of a beta-silicon carbide (β-SiC) crystal.

In the coating layer, the <111> crystal direction occupies 90% or more.

The coating layer may have a grain size of 2 μm or less.

According to another aspect of the inventive concept, a substrate treating apparatus may include a chamber having a treatment space therein, a supporting unit to support a substrate inside the treatment space, a gas supplying unit to supply process gas into the treatment space, and a plasma source to excite the process gas inside the treatment space. The supporting unit may include a supporting plate on which the substrate is placed, and an edge ring having a ring shape, provided around the supporting plate, and formed on an upper portion thereof with a coating layer having a grain size of 2 μm.

According to still another aspect of the inventive concept, a component of a substrate treating apparatus using plasma may include a base, and a coating layer formed on the base and having resistance against plasma. The coating layer may have a silicon carbide crystal developed in preferred orientation to <111> crystal direction of a beta-silicon carbide (β-SiC) crystal.

In addition, in the coating layer, the crystal having the <111> crystal direction occupies 90% or more of total crystals of the coating layer.

The coating layer has a grain size of 2 μm or less.

### BRIEF DESCRIPTION OF THE FIGURES

The above and other objects and features of the inventive concept will become apparent by describing in detail exemplary embodiments thereof with reference to the accompanying drawings.

FIG. 1 is a view illustrating a substrate treating apparatus, according to an embodiment of the inventive concept; and

FIG. 2 is an enlarged view of a part in which an edge ring is positioned in FIG. 1.

### DETAILED DESCRIPTION

Hereinafter, an embodiment of the inventive concept will be described in more detail with reference to the accompanying drawings. The embodiments of the inventive concept may be modified in various forms, and the scope of the inventive concept should not be construed to be limited by the embodiments of the inventive concept described in the following. The embodiments of the inventive concept are provided to describe the inventive concept for those skilled in the art more completely. Accordingly, the shapes and the like of the components in the drawings are exaggerated to emphasize clearer descriptions.

Hereinafter, description will be made with respect to a substrate treating apparatus capable of treating a substrate by producing plasma in an inductive coupled plasma (ICP) scheme, according to an embodiment of the inventive concept. However, the inventive concept is not limited to the above-described embodiments. For example, the substrate treating apparatus may be applied to various apparatuses which treat the substrate by using plasma produced in a conductively coupled plasma (CCP) scheme or a remote plasma scheme.

In addition, according to an embodiment of the inventive concept, an electrostatic chuck will be described by example of a supporting unit. However, the inventive concept is not limited, but the supporting unit may support the substrate through mechanical clapping or vacuum.

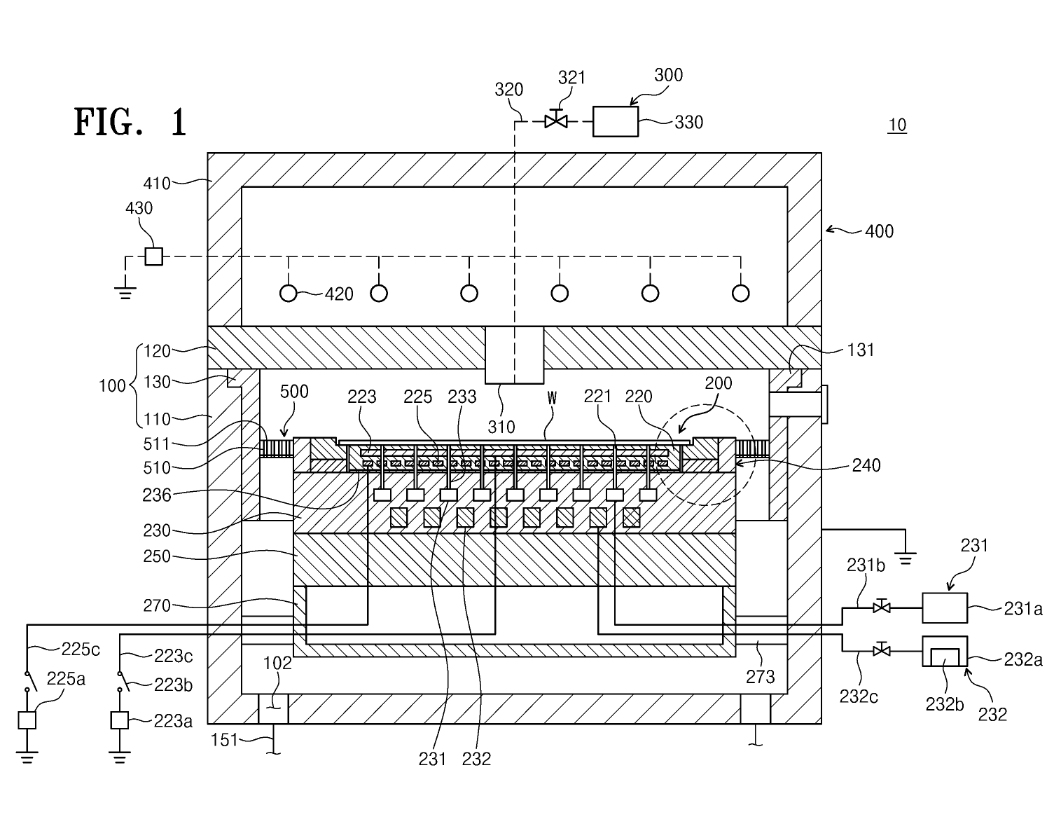

FIG. 1 is a view illustrating a substrate treating apparatus, according to an embodiment of the inventive concept.

Referring to FIG. 1, the substrate treating apparatus 10 treats a substrate “W” by using plasma. For example, the substrate treating apparatus 10 may perform an etching process with respect to the substrate “W”. The substrate treating apparatus 10 includes a chamber 100, a supporting unit 200, a gas supplying unit 300, a plasma source 400, and an exhaust unit 500.

The chamber 100 has a treatment space provided therein to treat the substrate “W”. The chamber 100 includes a housing 110 and a cover 120.

The housing 110 has an inner space having an open top surface. The inner space of the housing 110 is provided as a treatment space for performing a substrate treating process. The housing 110 is formed of a metallic material. The housing 110 may include aluminum (Al). The housing 110 may be grounded. The housing 110 is formed in the bottom surface thereof with an exhaust hole 102. The exhaust hole 102 is connected with an exhaust line 151. The reaction byproducts produced during the process and the gas staying in the inner space of the housing 110 may be discharged to the outside through the exhaust line 151. The internal pressure of the housing 110 is reduced to specific pressure through the exhaust process.

The cover 120 covers the open top surface of the housing 110. The cover 120 is provided in a plate shape to seal the inner space of the housing 110. The cover 120 may include a dielectric substance window.

The liner 130 is provided inside the housing 110. The liner 130 has an inner space having open top and bottom surfaces. The liner 130 may be provided in a cylindrical shape. The liner 130 may have a radius corresponding to the inner side surface of the housing 110. The liner 130 is provided along the inner side surface of the housing 110. A supporting ring 131 is formed on an upper end of the liner 130. The supporting ring 131 is provided in a ring-shaped plate and protrudes outward from the liner 130 along the circumference of the liner 130. The supporting ring 131 is placed on the upper end of the housing 110 to support the liner 130. The liner 130 may include the same material as that of the housing 110. The liner 130 may include Al. The liner 130 protects the inner side surface of the housing 110. When the process gas is excited, arc may be discharged inside the chamber 100. The arc discharge may damage peripheral devices. The liner 130 protects the inner side surface of the housing 110 to prevent the inner side surface of the housing 110 from being damaged due to the arc discharge. In addition, the reaction byproducts produced during the substrate treating process are prevented from being deposited on an inner sidewall of the housing 110. The liner 130 requires a lower cost and is more easily replaced with new one when comparing with the housing 110. Accordingly, when the liner 130 is damaged due to the arc discharge, a worker may replace the liner 130 with new one.

The supporting unit 200 supports the substrate “W” inside the treatment space inside the chamber 100. For example, the supporting unit 200 is provided inside the housing 110. The supporting unit 200 supports the substrate “W”. The supporting unit 200 may include an electrostatic chuck adsorbing the substrate “W” by using electrostatic force. Alternatively, the supporting unit 200 may support the substrate “W” in various manners such as mechanical clamping. Hereinafter, the supporting unit 200 including the electrostatic chuck will be described.

The supporting unit 200 includes chucks 220, 230, and 250, and an edge ring 240.

The chucks 220, 230, and 250 support the substrate W in process treatment. The chucks 220, 230, and 250 include a supporting plate 220, a fluid-passage-formed plate 230, and an insulating plate 250.

The supporting plate 220 is positioned on an upper end portion of the supporting unit 200. The supporting plate 220 may include a dielectric substance having a disc shape. The substrate “W” is placed on the top surface of the supporting plate 220. The top surface of the supporting plate 220 has a diameter smaller than that of the substrate “W”. The supporting plate 220 is formed therein with a first supply fluid passage 221 serving as a passage for supplying a heat transfer gas to the bottom surface of the substrate “W”. An electrostatic electrode 223 and a heater 225 are buried in the supporting plate 220.

The electrostatic electrode 223 is positioned above the heater 225. The electrostatic electrode 223 is electrically connected with a first lower power source 223a. Electrostatic force acts between the electrostatic electrode 223 and the substrate “W” by a current applied to the electrode 223 and the substrate “W” is adsorbed to the supporting plate 220 by the electrostatic force.

The heater 225 is electrically connected with a second lower power source 225a. The heater 225 resists a current applied thereto from the second lower power source 225a. The emitted heat is transferred to the substrate “W” through the supporting plate 220. The substrate “W” is maintained at a specific temperature by the heat emitted from the heater 225. The heater 225 includes a spiral-shaped coil. The fluid-passage-formed plate 230 is positioned at a lower portion of the supporting plate 220. The bottom surface of the supporting plate 220 may be bonded to the top surface of the fluid-passage-formed plate 230 by an adhesive 236.

The fluid-passage-formed plate 230 is positioned under the supporting plate 220.

The fluid-passage-formed plate 230 is formed therein with a first circulation fluid passage 231, a second circulation fluid passage 232, and a second supply fluid passage 233. The first circulation fluid passage 231 serves as a passage through which the heat transfer gas circulates. The second circulation fluid passage 232 serves as a passage through which a cooling fluid circulates. The second supply fluid passage 233 allows the first circulation fluid passage 231 to communicate with the first supply fluid passage 221. The first circulation fluid passage 231 serves as a passage through which the heat transfer gas circulates. The first circulation fluid passage 231 may be formed in a spiral shape inside the fluid-passage-formed plate 230. Alternatively, the first circulation fluid passage 231 may include ring-shaped fluid passages concentrically arranged with mutually different radiuses. First circulation fluid passages 231 may communicate with each other. The first circulation fluid passages 231 are formed at equal heights.

The first circulation fluid passage 231 is connected with a heat transfer medium storing unit 231a through a heat transfer medium supplying line 231b. A heat transfer medium is stored in the heat transfer medium storing unit 231a. According to an embodiment, the heat transfer medium includes inert gar. According to an embodiment, the heat transfer medium includes helium (He). The helium (He) gas is supplied to the first circulation fluid passage 231 through the heat transfer medium supplying line 231b, and is supplied to the bottom surface of the substrate “W” by sequentially passing through the second supply fluid passage 233 and the first supply fluid passage 221. The helium (He) gas serves as a medium helping the heat transfer between the substrate “W” and the supporting plate 220. Accordingly, the entire portion of the substrate W has a uniform temperature.

The second circulation fluid passage 232 is connected with a cooling fluid storing unit 232a through a cooling fluid supplying line 232c. The cooling fluid is stored in the cooling fluid storing unit 232a. A cooler 232b may be provided inside the cooling fluid storing unit 232a. The cooler 232b cools the cooling fluid to a specific temperature. Alternatively, the cooler 232b may be installed on the cooling fluid supplying line 232c. The cooling fluid supplied to the second circulation fluid passage 232 through the cooling fluid supplying line 232c circulates along the second circulation fluid passage 232 to cool the fluid-passage-formed plate 230. The fluid-passage-formed plate 230 is cooled while cooling the supporting plate 220 and the substrate “W” together, thereby maintaining the substrate “W” to the specific temperature. Accordingly, the lower portion of the edge ring 240 is generally provided at a temperature lower than that of the upper portion of the edge ring 240.

The insulating plate 250 is positioned under the fluid-passage-formed plate 230. The insulating plate 250 includes an insulating material to insulate the fluid-passage-formed plate 230 from the lower cover 270.

The lower cover 270 is positioned at the lower end of the supporting unit 200. The lower cover 270 may be spaced apart upward from the bottom surface of the housing 110. The lower cover 270 has an inner space having an open top surface. The top surface of the lower cover 270 is covered by the insulating plate 250. Accordingly, the outer diameter of the sectional surface of the lower cover 270 may be equal to the outer diameter of the insulating plate 250. A lift pin is positioned in the inner space of the lower cover 270 to receive the substrate “W” carried from an external carrying member and to seat the substrate “W”.

The lower cover 270 has a connection member 273. The connection member 273 connects an outer side surface of the lower cover 270 with an inner sidewall of the housing 110. A plurality of connection members 273 may be provided at regular distances on the outer side surface of the lower cover 270. The connection members 273 support the supporting unit 200 inside the chamber 100. In addition, the connection members 273 are connected with the inner wall of the housing 110 such that the lower cover 270 is electrically grounded. A first power line 223c connected with a first lower power source 223a, a second power line 225c connected with a second lower power source 225a, a heat transfer medium supplying line 231b connected with the heat transfer medium storing unit 231a, and a cooling fluid supplying line 232c connected with the cooling fluid storage unit 232a extend inside the lower cover 270 through the internal space of the connection member 273.

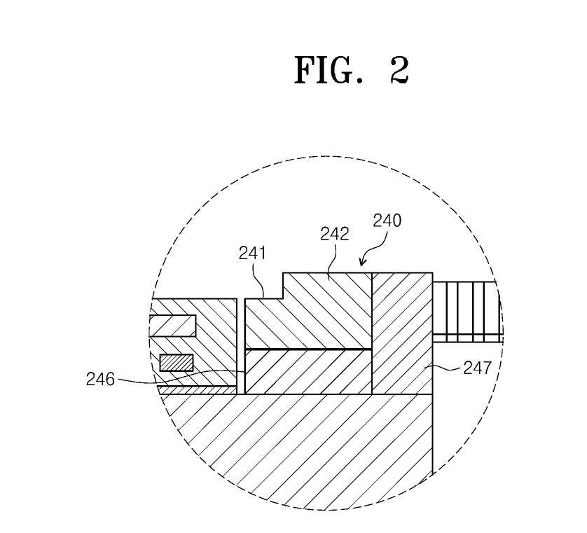

FIG. 2 is an enlarged view of a part in which an edge ring is positioned in FIG. 1.

Referring to FIGS. 1 and 2, an edge ring 240 is placed at an edge region of the supporting unit 200. The edge ring 240 has a ring shape and is provided to surround the supporting plate 220. For example, the edge ring 240 is provided along the circumference of the supporting plate 220.

An outer lateral side of the supporting plate 220 may be spaced apart from an inner lateral side of the edge ring 240 by a preset distance. The edge ring 240 adjusts the sheath and a plasma interface.

A first layer 241 and a second layer 242 may be formed on the top surface of the edge ring 240. The first layer 241 and the second layer 242 are distinguished based on the height of the edge ring 240.

The first layer 241 is positioned at an inner region of the edge ring 240.

The first layer 241 may be provided at the height corresponding to the top surface of the supporting plate 220 to support an outer region of the substrate “W”. For example, the first layer 242 may be provided at the same height as the height of the top surface of the supporting plate 220 to make contact with an outer bottom surface of the substrate “W”. Alternately, the first layer 241 may be provided lower than the top surface of the supporting plate 220 by a set dimension and a preset interval may be formed between the outer bottom surface of the substrate “W” and the first layer 241. The first layer 241 may be provided in the form of a plane shape while being parallel to the bottom surface of the substrate “W”.

The second layer 242 is formed to be higher than the first layer 241 while protruding upward from an outer end portion of the first layer 241.

As the sheath, the plasma interface, and the electric field is adjusted due to the difference in height between the first layer 241 and the second layer 242, plasma may be induced to the substrate W such that the plasma is focused on the substrate W. The edge ring 240 may formed of a conductive material. The edge ring 240 may be formed of silicon, silicon carbide, or the like.

A coupler 246 may be provided at a lower portion of the edge ring 240. The coupler 246 may fix the edge ring 240 to the fluid-passage-formed plate 230. The coupler 246 is formed of a material representing higher thermal conductivity. For example, the coupler 246 may be formed of a metallic material such as Al. In addition, the coupler 246 may be bonded to the top surface of the fluid-passage-formed plate 230 by a thermal conductive adhesive (not illustrated). In addition, the edge ring 240 may be bonded to the top surface of the coupler 246 by the thermal conductive adhesive (not illustrated). For example, the thermal conductive adhesive may employ a silicon pad.

In addition, the coupler 246 may be omitted and the edge ring 240 may directly make contact with the chucks 220, 230, and 250.

A shielding member 247 may be positioned outside the edge ring 240. The shielding member 247 is provided in a ring shape to surround the outside of the edge ring 240. The shielding member 247 prevents the lateral side of the edge ring 240 from being directly exposed to plasma or prevents plasma from being introduced into the side portion of the edge ring 240.

The edge ring 240 may be provided by forming a coating layer having resistance against the plasma on a base. For example, the edge ring 240 may be provided by forming a coating layer on the top surface of the base or the outer surface of the base. When the coating layer is formed on the top surface of the base, the coating layer is formed on the first layer and the second layer exposed to the coating layer.

The coating layer is formed of silicon carbide. The coating layer may be formed through a chemical vapor deposition (CVD) scheme, a physical vapor transport scheme (PVT).

The crystal of the coating layer is formed to be grown such that the direction of the crystal faces a specific direction. The crystal of the coating layer is formed as beta-silicon carbide (β-SiC) crystals having an isothiocyanate structure.

The coating layer is formed such that the crystal direction faces <111>.

TABLE 1

| Crystal | | Areal |
|---|---|---|
| direction | Area | density |
| 111 | (√3/2) a² | 1 |
| 220 | 2 a² | 1/2.3 |
| 311 | (√19/2)a² | 1/2.5 |

Table 1 shows the area in a specific crystal direction and the area density in the specified crystal direction when SiC has a beta-silicon carbide crystal shape.

Referring to Table 1, in the beta-silicon carbide crystal, a smaller area is formed in a <111> crystal direction rather than another crystal direction. Accordingly, the higher area density is formed in the <111> crystal direction. In addition, when the higher density is formed, the distance between atoms constituting the crystal may be reduced and thus the crystal may be densely formed.

The top surface of the edge ring 240 may be exposed to the plasma and to be etched, depending on the use of the substrate treating apparatus. Therefore, as the number of substrate treating processes is increased and the time for substrate treatment is elapsed, the top surface of the edge ring 240 is lowered in height by etching, thereby causing the sheath and the plasma interface to be changed in height. When the etching degree of the edge ring 240 exceeds a set value, the edge ring 240 has to be replaced.

When the crystal of the SiC is densely formed, the resistance against external mechanical and chemical force applied to the crystal is increased. Accordingly, as the crystal of the SiC coating layer is densely formed in the edge ring 240, the etching degree by the plasma is reduced and the use lifespan of the edge ring 240 is increased. For example, according to the inventive concept, the coating layer is formed such that the crystal direction of the coating layer faces <111>. Accordingly, the crystal having the <111> crystal direction occupies 90%.

σ_{y}=σ₀+kd^{-1/2} Equation 1

Equation 1 shows the relationship between the magnitude of the crystal and the yield strength. In Equation 1, σ₀ is an intrinsic value determined depending on the type of a material and provided as a constant. D represents the diameter of a crystal and k is a coefficient based on the type of a material.

Referring to FIG. 1, the yield strength and the size of the crystal are inversely proportional to each other. Accordingly, when a crystal is formed on the coating layer in the state that the size of the crystal is determined, the strength of the coating layer is lowered. According to the inventive concept, the coating layer of the edge ring 240 is grown while the size of the crystal is adjusted to be 2 μm. Accordingly, the coating layer has higher yield strength. In addition, when the yield strength is increased, crystals may have higher strength therebetween and thus the resistance against the plasma may be increased. In addition, according to the inventive concept, the coating layer of the edge ring 240 may be formed while the size of the crystal and the crystal direction are simultaneously adjusted

In addition, a coating layer having a crystal direction, or a grain size, or both the crystal direction and the grain size may be formed on the base such that an entire outer portion of a component except for the edge ring 240 or a part of the component exposed to the plasma has a resistance against the plasma.

According to an embodiment of the inventive concept, the component having the long lifespan and the substrate treating apparatus including the same may be provided.

The above description has been made for the illustrative purpose. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. The written embodiment describes the best state for implementing the technical spirit of the inventive concept, and various changes required in the detailed application fields and purposes of the inventive concept can be made. Furthermore, it should be construed that the attached claims include other embodiments.

While the inventive concept has been described with reference to exemplary embodiments thereof, it will be apparent to those of ordinary skill in the art that various changes and modifications may be made thereto without departing from the spirit and scope of the inventive concept as set forth in the following claims.

What is claimed is:

1. A substrate treating apparatus comprising:
a chamber having a treatment space therein;
a supporting unit to support a substrate inside the treatment space;
a gas supplying unit to supply process gas into the treatment space; and
a plasma source to ′ the process gas inside the treatment space,
wherein the supporting unit comprises:
a supporting plate on which the substrate is placed; and
an edge ring having a ring shape, provided around the supporting plate, and formed on an upper portion thereof with a coating layer having a silicon carbide crystal developed in preferred orientation to <111> crystal direction of a beta-silicon carbide (β-SiC) crystal.

2. The substrate treating apparatus of claim 1, wherein in the coating layer, the <111> crystal direction occupies 90% or more.

3. The substrate treating apparatus of claim 1, wherein the coating layer has a grain size of 2 μm or less.

4. A substrate treating apparatus comprising:
a chamber having a treatment space therein;
a supporting unit to support a substrate inside the treatment space;
a gas supplying unit to supply process gas into the treatment space; and
a plasma source to excite the process gas inside the treatment space,
wherein the supporting unit includes:
a supporting plate on which the substrate is placed; and
an edge ring having a ring shape, provided around the supporting plate, and formed on an upper portion thereof with a coating layer having a grain size of 2 μm.

5. A component of a substrate treating apparatus using plasma, the component comprising:
a base; and
a coating layer formed on the base and having resistance against plasma, and
wherein the coating layer has a silicon carbide crystal developed in preferred orientation to <111> crystal direction of a beta-silicon carbide (β-SiC) crystal.

6. The component of claim 5, wherein the crystal having the <111> crystal direction occupies 90% or more of total crystals of the coating layer.

7. The component of claim 5, wherein the coating layer has a grain size of 2 μm or less.
